(19) United States
(12) Patent Application Publication
(10) Pub. No.: US 2023/0038750 A1
(43) Pub. Date: Feb. 9, 2023

(54) PLASMA PROCESSING APPARATUS

(71) Applicant: Tokyo Electron Limited, Tokyo (JP)

(72) Inventor: Takahiro SHINDO, Yamanashi (JP)

(21) Appl. No.: 17/876,385

(22) Filed: Jul. 28, 2022

(30) Foreign Application Priority Data
Aug. 5, 2021 (JP) 2021-128840

(51) Int. Cl. H01J 37/32

(52) U.S. Cl. CPC H01J 37/32174; H01J 37/32568; H01J 37/32541; H01J 37/32577

(57) ABSTRACT

A plasma processing apparatus is provided. The apparatus comprises a chamber, a lower electrode, an upper electrode, a gas supply, an RF power supply and a circuit. The circuit is configured to provide a potential to the lower electrode and includes a first circuit and a second circuit. The first circuit has a rectifier, a capacitor, a first current path, and a second current path. In the first current path, the rectifier is electrically connected between the lower electrode and the capacitor, and the capacitor is electrically connected between the rectifier and the ground. In the second current path, the rectifier is electrically connected between the lower electrode and the ground. The rectifier is configured to allow a current to flow toward the capacitor in the first current path and to allow a current to flow toward the lower electrode in the second current path. The second circuit is electrically connected to the capacitor and is configured to provide a voltage generated in the capacitor.

### CROSS-REFERENCE TO RELATED APPLICATIONS

This application claims priority to Japanese Patent Application No. 2021-128840 filed on Aug. 5, 2021, the entire contents of which are incorporated herein by reference.

### TECHNICAL FIELD

An exemplary embodiment of the present disclosure relates to a plasma processing apparatus.

### BACKGROUND

Plasma processing is often used as processing for a substrate such as a semiconductor wafer or the like. Japanese Laid-open Patent Publication No. H11-031685 and Japanese Laid-open Patent Publication No. 2015-124397 disclose techniques for controlling an impedance of a current path for a radio frequency (RF) current used for plasma generation that is connected to a lower electrode.

### SUMMARY

The present disclosure provides a technique for reducing energy of ions incident on a lower electrode.

According to one aspect of the present disclosure, a plasma processing apparatus is provided. The plasma processing apparatus comprises a chamber, a lower electrode, an upper electrode, a gas supply, an RF power supply and a circuit. The lower electrode is included in a substrate support disposed in the chamber. The upper electrode is disposed to face the lower electrode. The gas supply is configured to supply a processing gas to a gap between the upper electrode and the lower electrode. The RF power supply is configured to generate plasma of the processing gas by applying an RF voltage to the upper electrode. The circuit is electrically connected between the lower electrode and the ground and configured to provide a potential to the lower electrode. The circuit includes a first circuit and a second circuit. The first circuit has a rectifier, a capacitor, a first current path, and a second current path. Both the first current path and the second current path are disposed between the lower electrode and the ground. In the first current path, the rectifier is electrically connected between the lower electrode and the capacitor, and the capacitor is electrically connected between the rectifier and the ground. In the second current path, the rectifier is electrically connected between the lower electrode and the ground. The rectifier is configured to allow a current to flow toward the capacitor in the first current path and to allow a current to flow toward the lower electrode in the second current path. The second circuit is electrically connected to the capacitor and is configured to provide a voltage generated in the capacitor.

### BRIEF DESCRIPTION OF THE DRAWINGS

The objects and features of the present disclosure will become apparent from the following description of embodiments, given in conjunction with the accompanying drawings, in which:

FIG. 1 schematically shows a plasma processing apparatus according to one exemplary embodiment;

FIG. 2 shows an example of a circuit shown in FIG. 1;

FIG. 3 shows an example of a first circuit shown in FIG. 2;

FIG. 4 shows an example of a third circuit shown in FIG. 2;

FIG. 5 shows an example of a second circuit shown in FIG. 2;

FIG. 6 shows a simulation result illustrating the effect of the circuit shown in FIG. 2;

FIG. 7 shows another example of the first circuit shown in FIG. 2;

FIG. 8 shows another example of the second circuit shown in FIG. 2;

FIG. 9 shows another example of the second circuit shown in FIG. 2; and

FIG. 10 shows another example of the second circuit shown in FIG. 2.

### DETAILED DESCRIPTION

Hereinafter, various exemplary embodiments will be described.

According to one aspect of the present disclosure, a plasma processing apparatus is provided. The plasma processing apparatus comprises a chamber, a lower electrode, an upper electrode, a gas supply, an RF power supply and a circuit. The lower electrode is included in a substrate support disposed in the chamber. The upper electrode is disposed to face the lower electrode. The gas supply is configured to supply a processing gas to a gap between the upper electrode and the lower electrode. The RF power supply is configured to generate plasma of the processing gas by applying an RF voltage to the upper electrode. The circuit is electrically connected between the lower electrode and the ground and configured to provide a potential to the lower electrode. The circuit includes a first circuit and a second circuit. The first circuit has a rectifier, a capacitor, a first current path, and a second current path. Both the first current path and the second current path are disposed between the lower electrode and the ground. In the first current path, the rectifier is electrically connected between the lower electrode and the capacitor, and the capacitor is electrically connected between the rectifier and the ground. In the second current path, the rectifier is electrically connected between the lower electrode and the ground. The rectifier is configured to allow a current to flow toward the capacitor in the first current path and to allow a current to flow toward the lower electrode in the second current path. The second circuit is electrically connected to the capacitor and is configured to provide a voltage generated in the capacitor.

In accordance with one exemplary embodiment, the potential of the lower electrode is provided by the voltage generated in the capacitor, and the voltage generated in the capacitor is provided by the second circuit. Since the potential of the lower electrode is adjusted by the circuit having the capacitor, the second circuit, and the like, the RF power passing through the substrate support including the lower electrode is controlled during the plasma processing. By controlling the RF power passing through the substrate support, the sheath voltage formed on the surface of the substrate placed on the substrate support is controlled and, thus, the amount of ions incident on the substrate and the substrate support is controlled during the plasma processing. Hence, by controlling the amount of ions, the energy provided by the ions incident on the lower electrode is reduced.

In accordance with one exemplary embodiment, the rectifier has a first element and a second element. The first element may be a first diode, which is electrically connected between the lower electrode and the capacitor in the first current path. The second element may be a second diode, which is electrically connected between the lower electrode and the ground in the second current path. The cathode of the first diode is electrically connected to the capacitor and the anode of the first diode is electrically connected to the lower electrode. The cathode of the second diode is electrically connected to the lower electrode and the anode of the second diode is electrically grounded.

In accordance with one exemplary embodiment, the rectifier has a first element, a second element, and a driving circuit. The rectifier is electrically connected to the RF power supply through the driving circuit. The first element may be a first switching element, which is electrically connected between the lower electrode and the capacitor in the first current path. The second element may be a second switching element, which is electrically connected to the lower electrode and the ground in the second current path. The driving circuit is electrically connected to the first switching element and the second switching element. The driving circuit is configured to control on/off of the first switching element and the second switching element based on a waveform of the RF voltage outputted from the RF power supply.

In accordance with one exemplary embodiment, both the first switching element and the second switching element may be transistors.

In accordance with one exemplary embodiment, the second circuit may be a variable DC power supply. A positive electrode of the variable DC power supply is electrically connected to the capacitor, and a negative electrode of the variable DC power supply is electrically grounded.

In accordance with one exemplary embodiment, the second circuit may be a Zener diode. A cathode of the Zener diode is electrically connected to the capacitor and an anode of the Zener diode is electrically grounded.

In accordance with one exemplary embodiment, the second circuit has a Zener diode, a resistance element, and a transistor. A cathode of the Zener diode and a collector of the transistor are electrically connected to the capacitor. An anode of the Zener diode and a base of the transistor are electrically grounded through the resistance element. An emitter of the transistor is electrically grounded.

In accordance with one exemplary embodiment, the second circuit is a variable resistance element.

In accordance with one exemplary embodiment, the circuit further comprises a third circuit. The third circuit is electrically connected between the first circuit and the second circuit and is configured to shield an RF voltage. The third circuit has a capacitor and an inductor. The capacitor and the inductor of the third circuit are electrically connected in parallel between the capacitor of the first circuit and the second circuit.

In accordance with one exemplary embodiment, the plasma processing apparatus further comprises a ring electrode that is disposed around the lower electrode and is electrically grounded.

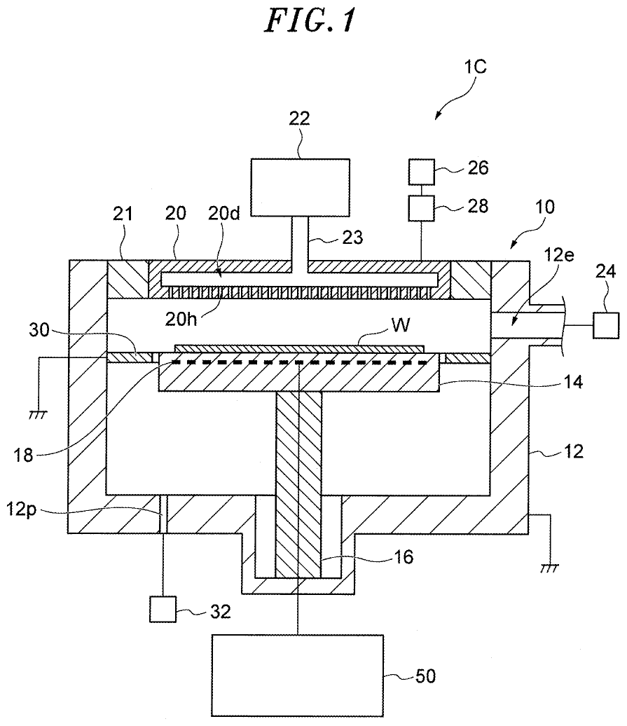

Hereinafter, various exemplary embodiments will be described in detail with reference to the accompanying drawings. Like reference numerals will be given to like or corresponding parts throughout the drawings. FIG. 1 schematically shows a plasma processing apparatus according to one exemplary embodiment. The plasma processing apparatus 1 shown in FIG. 1 includes a chamber 10. The chamber 10 has an inner space. The chamber 10 may include a chamber body 12. The chamber body 12 has a substantially cylindrical shape. The inner space of the chamber 10 is disposed in the chamber body 12. The chamber body 12 is made of a metal such as aluminum. The chamber body 12 is electrically grounded. The sidewall of the chamber body 12 may provide a passage through which the substrate W is transferred. Further, a gate valve may be disposed along the sidewall of the chamber body 12 so that the passage can be opened and closed.

The plasma processing apparatus 1 further includes a substrate support 14. The substrate support 14 is disposed in the chamber 10. The substrate support 14 is configured to support the substrate W placed on the substrate support 14. The substrate support 14 has a main body. The main body of the substrate support 14 may be made of, e.g., aluminum nitride, and may have a disc shape. The substrate support 14 may be supported by a support member 16. The support member 16 extends upward from the bottom portion of the chamber 10. The substrate support 14 includes a lower electrode 18. The lower electrode 18 is included in the substrate support 14, and is embedded in the main body of the substrate support 14.

The plasma processing apparatus 1 further includes an upper electrode 20. The upper electrode 20 is disposed above the substrate support 14. The upper electrode 20 is disposed to face the lower electrode 18. The upper electrode 20 forms the ceiling of the chamber 10. The upper electrode 20 is electrically insulated from the chamber body 12. In one embodiment, the upper electrode 20 is fixed to the upper portion of the chamber body 12 via an insulating member 21.

In one embodiment, the upper electrode 20 serves as a shower head. The upper electrode 20 has therein a gas diffusion space 20d. Further, the upper electrode 20 further has a plurality of gas holes 20h. The plurality of gas holes 20h extend downward from the gas diffusion space 20d and open toward the inner space of the chamber 10. In other words, the plurality of gas holes 20h connect the gas diffusion space 20d and the inner space of the chamber 10.

The plasma processing apparatus 1 further includes a gas supply device 22. The gas supply device 22 is configured to supply a gas into the chamber 10. The gas supply device 22 is configured to supply a processing gas to a gap between the upper electrode 20 and the lower electrode 18. The gas supply device 22 is connected to the gas diffusion space 20d through a line 23. The gas supply device 22 may have one or more gas sources, one or more flow rate controllers, and one or more on/off valves. One or more gas sources are connected to the line 23 through corresponding flow rate controllers and corresponding on/off valves.

In one embodiment, the gas supply device 22 may supply a film forming gas. In other words, the plasma processing apparatus 1 may be a film forming apparatus. An insulating film may be formed on the substrate W by the film forming gas. In another embodiment, the gas supply device 22 may supply an etching gas. In other words, the plasma processing apparatus 1 may be a plasma etching apparatus.

The plasma processing apparatus 1 further includes an exhaust device 24. The exhaust device 24 includes a pressure controller such as an automatic pressure control valve and a vacuum pump such as a turbo molecular pump or a dry pump. The exhaust device 24 is connected to the inner space of the chamber 10 from an exhaust port 12e disposed on the sidewall of the chamber body 12 through an exhaust line.

The plasma processing apparatus 1 further includes a radio frequency (RF) power supply 26. The RF power supply 26 is configured to generate plasma of the processing gas supplied from the gas supply device 22 to the gap between the upper electrode 20 and the lower electrode 18 by applying an RF voltage to the upper electrode 20. In one embodiment, the RF power supply 26 generates an RF power. The RF power may have any frequency. The frequency of the RF power may be 13.56 MHz or less. The frequency of the RF power may be 2 MHz or less. The frequency of the RF power may be 20 kHz or higher.

The RF power supply 26 is connected to the upper electrode 20 through a matching device 28. The RF power from the RF power supply 26 is supplied to the upper electrode 20 through the matching device 28. The matching device 28 has a matching circuit for matching the impedance of the load of the RF power supply 26 to the output impedance of the RF power supply 26.

In another embodiment, the RF power supply 26 may be configured to periodically apply a pulse of a DC voltage to the upper electrode 20. The frequency that specifies the period in which the pulse of the DC voltage from the RF power supply 26 is applied to the upper electrode 20 is, e.g., 10 kHz or higher and 10 MHz or less. When the RF power supply 26 is configured to periodically apply a pulse of a DC voltage to the upper electrode 20, the plasma processing apparatus 1 may not include the matching device 28.

The plasma processing apparatus 1 further includes a ring electrode 30. The ring electrode 30 has a ring shape. The ring electrode 30 may be divided into multiple electrodes arranged along a circumferential direction. The ring electrode 30 is disposed around the substrate support 14 to surround the outer periphery of the substrate support 14. Although a gap exists between the ring electrode 30 and the outer periphery of the substrate support 14, the gap may not exist. The ring electrode 30 is electrically grounded.

In one embodiment, the plasma processing apparatus 1 further includes a gas supply device 32. The gas supply device 32 supplies a purge gas so that the purge gas can flow upward through the gap between the ring electrode 30 and the substrate support 14. The gas supply device 32 supplies a purge gas into the chamber 10 through a gas inlet port 12p. In the illustrated example, the gas inlet port 12p is disposed at the wall of the chamber body 12 to be located below the substrate support 14. The purge gas supplied by the gas supply device 32 may be an inert gas, or may be a noble gas, for example.

When the substrate W is subjected to plasma processing in the plasma processing apparatus 1, the processing gas is supplied from the gas supply device 22 into the chamber 10. Then, a pulse of a DC voltage or an RF power from the RF power supply 26 is applied to the upper electrode 20. Accordingly, plasma is produced from the processing gas in the chamber 10. The substrate W on the substrate support 14 is processed by chemical species from the produced plasma. For example, the chemical species from plasma forms a film on the substrate W. Alternatively, the chemical species from the plasma etch the substrate W.

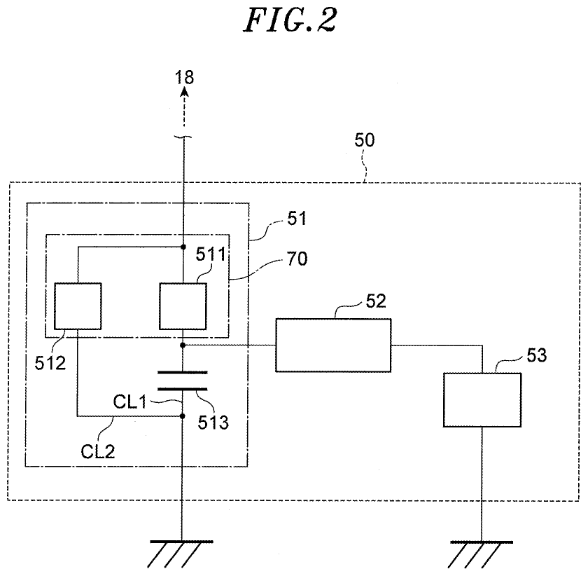

The plasma processing apparatus 1 further includes a circuit 50. The configuration of the circuit 50 in one embodiment is shown in FIG. 2. FIG. 2 shows an example of the circuit 50. The circuit 50 is electrically connected between the lower electrode 18 and the ground. The circuit 50 is configured to provide a potential to the lower electrode 18.

The circuit 50 includes a first circuit 51, a second circuit 53, and a third circuit 52. The first circuit 51 has a rectifier 70, a capacitor 513, a first current path CL1, and a second current path CL2. The second circuit 53 is electrically connected to the capacitor 513. The second circuit 53 is configured to provide the voltage generated in the capacitor 513. The second circuit 53 may use an active device having a function of supplying charges from outside, such as a single power supply or a bipolar power supply, or may use a passive device having a function of controlling a voltage, such as a Zener diode, a fixed resistance, or an electronic load.

The third circuit 52 is electrically connected between the first circuit 51 and the second circuit 53. The third circuit 52 is configured to shield an RF voltage signal.

The potential of the lower electrode 18 is provided by the voltage generated in the capacitor 513 and the voltage generated in the capacitor 513 is provided by the second circuit 53. Since the potential of the lower electrode 18 is adjusted by the circuit 50 having the capacitor 513, the second circuit 53, and the like, the RF power passing through the substrate support 14 including the lower electrode 18 is controlled during the plasma processing. By controlling the RF power passing through the substrate support 14, the sheath voltage formed on the surface of the substrate W placed on the substrate support 14 is controlled and, thus, the amount of ions incident on the substrate W and the substrate support 14 is controlled during the plasma processing. Hence, by controlling the amount of ions, the energy provided by the ions incident on the lower electrode 18 is reduced.

Both the first current path CL1 and the second current path CL2 are disposed between the lower electrode 18 and the ground. Two current paths are provided between the lower electrode 18 and the ground by the first current path CL1 and the second current path CL2. In the first current path CL1, the rectifier 70 is electrically connected between the lower electrode 18 and the capacitor 513. In the first current path CL 1, the capacitor 513 is electrically connected between the rectifier 70 and the ground. In the second current path CL2, the rectifier 70 is electrically connected between the lower electrode 18 and the ground.

The rectifier 70 is configured to allow a current to flow toward the capacitor 513 in the first current path CL1. The rectifier 70 is configured to allow a current to flow toward the lower electrode 18 in the second current path CL2.

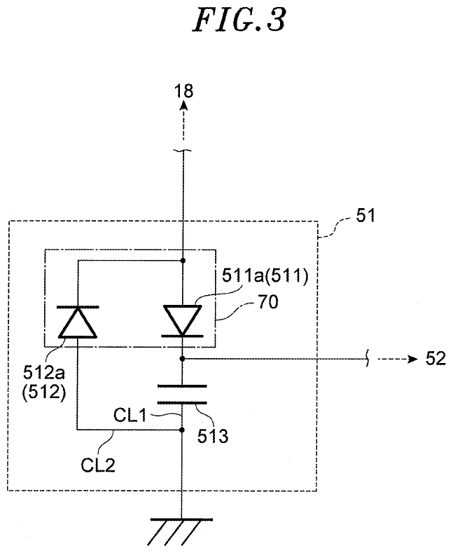

FIG. 3 shows an example of the first circuit 51 shown in FIG. 2. The rectifier 70 in one embodiment shown in FIG. 3 has a first element 511 and a second element 512. The first element 511 may be a first diode 511a. The first diode 511a is electrically connected between the lower electrode 18 and the capacitor 513 in the first current path CL1. The second element 512 may be a second diode 512a. The second diode 512a is electrically connected between the lower electrode 18 and the ground in the second current path CL2. The cathode of the first diode 511a is electrically connected to the capacitor 513. The anode of the first diode 511a is electrically connected to the lower electrode 18. The cathode of the second diode 512a is electrically connected to the lower electrode 18. The anode of the second die 512a is electrically grounded. The rectifier 70 having the first diode 511a and the second diode 512a shown in FIG. 3 can appropriately rectify the current flowing from the lower electrode 18 using the RF power during the plasma processing.

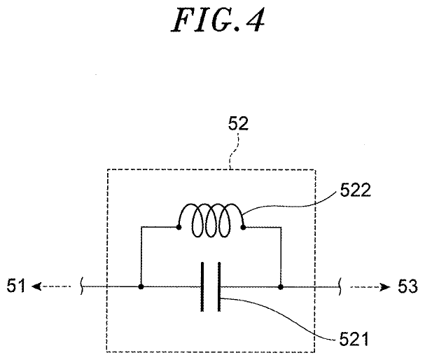

FIG. 4 shows an example of the third circuit 52 shown in FIG. 2. The third circuit 52 in one embodiment shown in FIG. 4 has a capacitor 521 and an inductor 522. The capacitor 521 and the inductor 522 are electrically connected in parallel between the capacitor 513 and the second circuit 53. Accordingly, the third circuit 52 can shield the RF voltage signal propagating between the first circuit 51 and the second circuit 53.

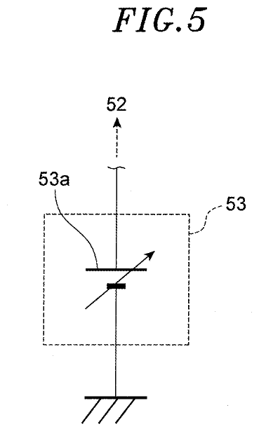

FIG. 5 shows an example of the second circuit 53 shown in FIG. 2. The second circuit 53 in one embodiment shown in FIG. 5 is a variable DC power supply 53a. The positive electrode of the variable DC power supply 53a is electrically connected to the capacitor 513. The negative electrode of the variable DC power supply 53a is electrically grounded. The variable DC power supply 53a shown in FIG. 5 can appropriately provide a voltage to the capacitor 513.

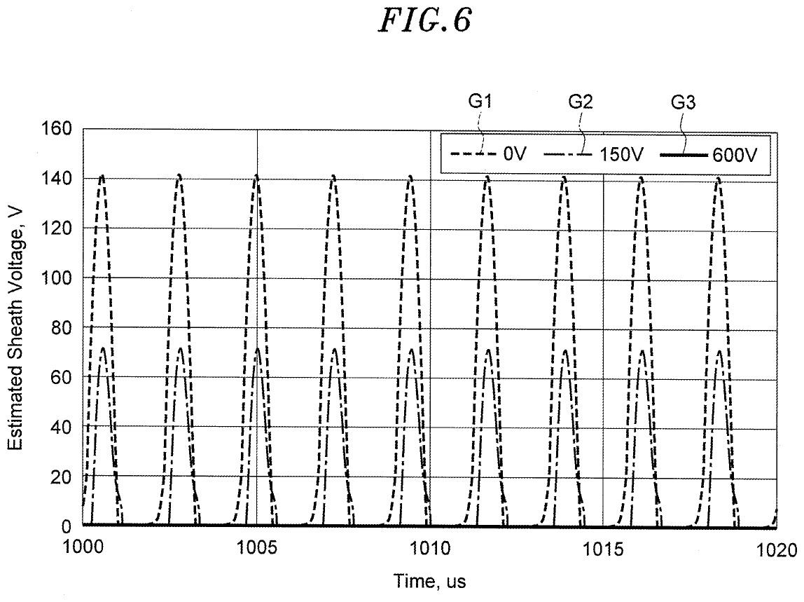

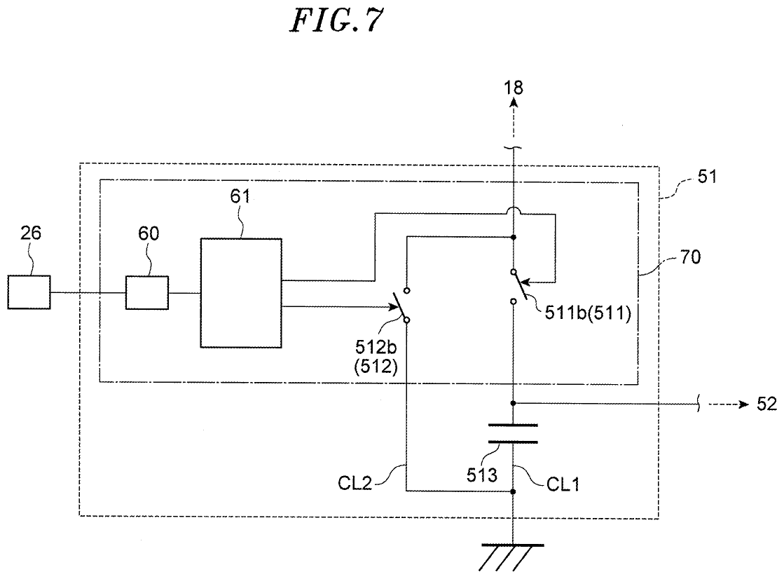

The effect of adjusting the potential of the lower electrode 18 by the circuit 50 will be described with reference to FIG. 6. The following description with reference to FIG. 6 is the same for other configurations of the first circuit 51 and the second circuit 53 shown in FIGS. 7 to 10.

The horizontal axis of FIG. 6 represents time (us). The vertical axis of FIG. 6 represents a sheath voltage (V) formed on the surface of the substrate W placed on the substrate support 14. The results shown in FIG. 6 (waveforms G1, G2, and G3) are obtained by simulation. The waveform G1 represents the waveform of the sheath voltage generated when the voltage provided to the lower electrode 18 by the capacitor 513 is 0 (V). The waveform G2 represents the waveform of the sheath voltage generated when the voltage provided to the lower electrode 18 by the capacitor 513 is 150 (V). The waveform G3 represents the waveform of the sheath voltage generated when the voltage provided to the lower electrode 18 by the capacitor 513 is 600 (V).

Referring to FIG. 6, it is clear that the sheath voltage formed on the surface of the substrate W placed on the substrate support 14 is reduced as the voltage of the capacitor 513 provided to the lower electrode 18 is increased at least from 0 (V) to 600 (V). Therefore, as the potential of the capacitor 513 increases, the amount of ions incident on the substrate W and the substrate support 14 during plasma processing is reduced. By controlling the voltage generated in the capacitor 513, it is possible to control the amount of ions incident on the substrate W and the substrate support 14 during the plasma processing. Accordingly, by controlling the amount of ions, the energy provided by the ions incident on the lower electrode 18 is reduced.

Hereinafter, other configurations of the first circuit 51 and the second circuit 53 that may be included in the plasma processing apparatus 1 will be described with reference to FIGS. 7 to 10.

FIG. 7 shows another example of the first circuit 51 shown in FIG. 2. The rectifier 70 in one embodiment shown in FIG. 7 may include a first element 511, a second element 512, a detection circuit 60, and a driving circuit 61. The rectifier 70 is electrically connected to the RF power supply 26 through the driving circuit 61 and the detection circuit 60. The first element 511 may be a first switching element 511b electrically connected between the lower electrode 18 and the capacitor 513 in the first current path CL1. The second element 512 may be a second switching element 512b electrically connected to the lower electrode 18 and ground in the second current path CL2. Both the first switching element 511b and the second switching element 512b may be transistors.

The detection circuit 60 may be a voltage probe for detecting a waveform of an RF voltage outputted from the RF power supply 26. For example, more specifically, the detection circuit 60 can detect whether the RF voltage outputted from the RF power supply 26 is on the positive side or the negative side from 0 (V) that is the vibration center. The detection circuit 60 outputs a detection signal indicating the detection result to the driving circuit 61.

The driving circuit 61 is electrically connected to the first switching element 511b and the second switching element 512b. The driving circuit 61 is configured to control on/off of the first switching element 511b and the second switching element 512b based on the waveform of the RF voltage outputted from the RF power supply 26. More specifically, the driving circuit 61 outputs a signal for instructing on/off of each of the first switching element 511b and the second switching element 512b in response to the above-described detection signal outputted from the detection circuit 60. Therefore, similarly to the rectifier 70 having the first diode 511a and the second diode 512a shown in FIG. 3, the rectifier 70 shown in FIG. 7 can appropriately rectify the current flowing from the lower electrode 18. The detection circuit 60 may be included in the driving circuit 61, or may be separate from the driving circuit 61 as shown in FIG. 7.

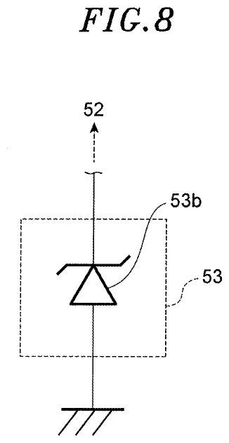

FIG. 8 shows another example of the second circuit 53 shown in FIG. 2. The second circuit 53 in one embodiment shown in FIG. 8 may be a Zener diode 53b. The cathode of the Zener diode 53b is electrically connected to the capacitor 513. The anode of the Zener diode 53b is electrically grounded. The second circuit 53 having the Zener diode 53b shown in FIG. 8 also can appropriately provide a voltage to the capacitor 513.

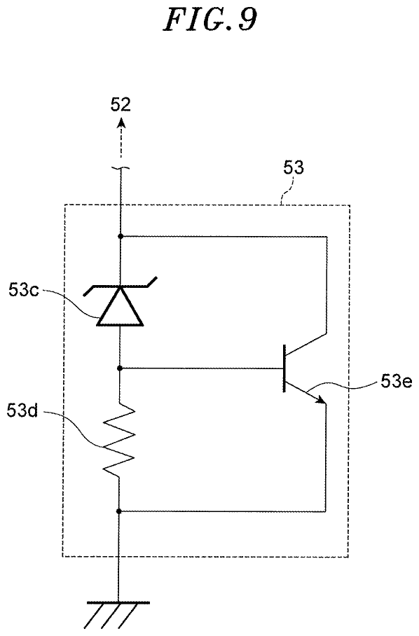

FIG. 9 shows another example of the second circuit 53 shown in FIG. 2. The second circuit 53 in one embodiment shown in FIG. 9 may include a Zener diode 53c, a resistance element 53d, and a transistor 53e. The cathode of the Zener diode 53c and the collector of the transistor 53e are electrically connected to the capacitor 513. The anode of the Zener diode 53c and the base of the transistor 53e are electrically grounded through the resistance element 53d. The emitter of the transistor 53e is electrically grounded. The second circuit 53 having a Zener diode 53c, a resistance element 53d, and a transistor 53e shown in FIG. 9 also can appropriately provide a voltage to the capacitor 513, similarly to the second circuit 53 shown in FIG. 8.

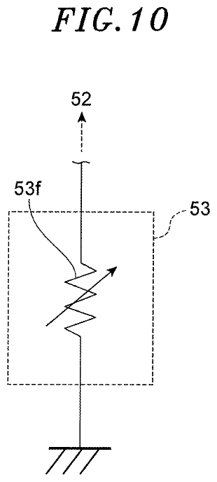

FIG. 10 shows another example of the second circuit 53 shown in FIG. 2. The second circuit 53 in one embodiment shown in FIG. 10 may be a variable resistance element 53f The second circuit 53 of the variable resistance element 53f shown in FIG. 10 also can appropriately provide a voltage to the capacitor 513, similarly to the second circuit 53 shown in FIGS. 8 and 9. An electronic load that is a device for electronically controlling the variable resistance may be used instead of the variable resistance element 53f.

While various embodiments have been described above, the present disclosure is not limited to the above-described embodiments, and various additions, omissions, substitutions and changes may be made. Further, other embodiments can be implemented by combining elements in different embodiments.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a chamber;
a lower electrode included in a substrate support disposed in the chamber;
an upper electrode disposed to face the lower electrode;
a gas supply device configured to supply a processing gas to a gap between the upper electrode and the lower electrode;
an RF power supply configured to generate plasma of the processing gas by applying an RF voltage to the upper electrode; and
a circuit electrically connected between the lower electrode and ground and configured to provide a potential to the lower electrode,
wherein the circuit includes a first circuit and a second circuit,
the first circuit has a rectifier, a capacitor, a first current path, and a second current path,
both the first current path and the second current path are disposed between the lower electrode and the ground,
in the first current path, the rectifier is electrically connected between the lower electrode and the capacitor, and the capacitor is electrically connected between the rectifier and the ground,
in the second current path, the rectifier is electrically connected between the lower electrode and the ground,
the rectifier is configured to allow a current to flow toward the capacitor in the first current path and to allow a current to flow toward the lower electrode in the second current path, and
the second circuit is electrically connected to the capacitor and is configured to provide a voltage generated in the capacitor.

2. The plasma processing apparatus of claim 1, wherein the rectifier has a first element and a second element,
the first element is a first diode electrically connected between the lower electrode and the capacitor in the first current path,
the second element is a second diode electrically connected between the lower electrode and the ground in the second current path,
a cathode of the first diode is electrically connected to the capacitor and an anode of the first diode is electrically connected to the lower electrode, and
a cathode of the second diode is electrically connected to the lower electrode and an anode of the second diode is electrically grounded.

3. The plasma processing apparatus of claim 1, wherein the rectifier has a first element, a second element, and a driving circuit, and is electrically connected to the RF power supply through the driving circuit,
the first element is a first switching element electrically connected between the lower electrode and the capacitor in the first current path,
the second element is a second switching element electrically connected to the lower electrode and the ground in the second current path, and
the driving circuit is electrically connected to the first switching element and the second switching element, and is configured to control on/off of the first switching element and the second switching element based on a waveform of the RF voltage outputted from the RF power supply.

4. The plasma processing apparatus of claim 3, wherein both the first switching element and the second switching element are transistors.

5. The plasma processing apparatus of claim 1, wherein the second circuit is a variable DC power supply, and
a positive electrode of the variable DC power supply is electrically connected to the capacitor, and a negative electrode of the variable DC power supply is electrically grounded.

6. The plasma processing apparatus of claim 2, wherein the second circuit is a variable DC power supply, and
a positive electrode of the variable DC power supply is electrically connected to the capacitor, and a negative electrode of the variable DC power supply is electrically grounded.

7. The plasma processing apparatus of claim 1, wherein the second circuit is a Zener diode, and
a cathode of the Zener diode is electrically connected to the capacitor and an anode of the Zener diode is electrically grounded.

8. The plasma processing apparatus of claim 2, wherein the second circuit is a Zener diode, and
a cathode of the Zener diode is electrically connected to the capacitor and an anode of the Zener diode is electrically grounded.

9. The plasma processing apparatus of claim 1, wherein the second circuit has a Zener diode, a resistance element, and a transistor,
a cathode of the Zener diode and a collector of the transistor are electrically connected to the capacitor,
an anode of the Zener diode and a base of the transistor are electrically grounded through the resistance element, and
an emitter of the transistor is electrically grounded.

10. The plasma processing apparatus of claim 2, wherein the second circuit has a Zener diode, a resistance element, and a transistor,
a cathode of the Zener diode and a collector of the transistor are electrically connected to the capacitor,
an anode of the Zener diode and a base of the transistor are electrically grounded through the resistance element, and
an emitter of the transistor is electrically grounded.

11. The plasma processing apparatus of claim 1, wherein the second circuit is a variable resistance element.

12. The plasma processing apparatus of claim 2, wherein the second circuit is a variable resistance element.

13. The plasma processing apparatus of claim 1, further comprising:
a third circuit electrically connected between the first circuit and the second circuit and configured to shield an RF voltage,
wherein the third circuit has a capacitor and an inductor, and
the capacitor and the inductor of the third circuit are electrically connected in parallel between the capacitor of the first circuit and the second circuit.

14. The plasma processing apparatus of claim 2, further comprising:
a third circuit electrically connected between the first circuit and the second circuit and configured to shield an RF voltage,
wherein the third circuit has a capacitor and an inductor, and
the capacitor and the inductor of the third circuit are electrically connected in parallel between the capacitor of the first circuit and the second circuit.

15. The plasma processing apparatus of claim 3, further comprising:
a third circuit electrically connected between the first circuit and the second circuit and configured to shield an RF voltage,
wherein the third circuit has a capacitor and an inductor, and
the capacitor and the inductor of the third circuit are electrically connected in parallel between the capacitor of the first circuit and the second circuit.

16. The plasma processing apparatus of claim 1, further comprising a ring electrode that is disposed around the lower electrode and is electrically grounded.

17. The plasma processing apparatus of claim 2, further comprising a ring electrode that is disposed around the lower electrode and is electrically grounded.

18. The plasma processing apparatus of claim 3, further comprising a ring electrode that is disposed around the lower electrode and is electrically grounded.
